(19) United States
(12) Patent Application Publication
(10) Pub. No.: US 2020/0191224 A1
(43) Pub. Date: Jun. 18, 2020

(54) DAMPER

(71) Applicant: Hsin Hung Precision Technology Co., Ltd., Tainan City (TW)

(72) Inventor: Hung-Shih Hsu, Tainan City (TW)

(21) Appl. No.: 16/217,929

(22) Filed: Dec. 12, 2018

(51) Int. Cl. F16F 3/12; F16F 15/08

(52) U.S. Cl. CPC F16F 3/12; F16F 15/085; F16F 2224/025; H01L 21/67369; F16F 2232/08; F16F 2236/04; F16F 2224/0208

(57) ABSTRACT

A damper includes a top board mounted in a chamber of an elastic rubber sleeve to shield an assembly port of the elastic rubber sleeve, at least one first elastic pad disposed in the chamber of the elastic rubber sleeve, and a compression spring disposed between the first elastic pad and the top board. The compression spring provides a more reliable action stroke to completely absorb the external impact or vibration energy. More particularly, when the external impact or vibration force disappears, the energy stored by the compression spring can quickly recover the elastic rubber sleeve, and effectively enhance a vibration absorption effect and a response speed of the overall damper.

### BACKGROUND OF THE INVENTION

### (1) Field of the Invention

The invention relates to a damper, and more particularly to a damper capable of providing better vibration absorption effects, and thus enhancing the object delivery success rate.

### (2) Description of the Prior Art

In order to decrease the possibility that wafers are damaged in a transporting process in a highly managed cleanroom, an overhead hoist transport (OHT) is usually used to transport the wafers, so that the ceiling and the space above the machine can be effectively utilized and the wafer transporting works can be rapidly and stably performed between processing areas.

As shown in FIG. 1, a motor (not shown) of an OHT 11 with similar functions mainly drives a lifting device constituted by a belt 12 and a jaw 13. The jaw 13 grabs an object 20 disposed below the OHT 11, and several dampers 14 are disposed on a bottom surface of the OHT 11 to absorb the bottom surface of the object 20, which may be generated when the object 20 approaches the OHT 11 at a high speed, and to prevent the object 20 from shaking when the OHT 11 is moved.

Furthermore, in the transport process of the typical OHT, the object 20 hung by the OHT 11 bears the G-force, generated when the OHT speeds up, stops and turns. However, similar to the damper 14 used in the conventional OHT, only several silicone pads 142 are placed in a rubber sleeve 141. Thus, the vibration absorption effect, the vibration absorption stroke and the response speed, which can be provided, are further restricted.

More particularly, when the to-be-protected object is the wafer which needs to be well protected, although the wafer is stored in the wafer storage box and shielded, the wafer still may be ruptured by collision, or the friction between the wafer and the wafer storage box may present to generate the dust or particles, which contaminate the wafer, thereby seriously affecting the output value and the production capacity of the wafer.

### SUMMARY OF THE INVENTION

In view of this, a main objective of the invention is to provide a damper capable of providing better vibration absorption effects, and thus enhancing the object delivery success rate.

The damper of the invention basically includes: an elastic rubber sleeve, a top board, at least one first elastic pad and a compression spring. The elastic rubber sleeve has a substantially straight cylindrical chamber formed inside the elastic rubber sleeve, a top portion of the elastic rubber sleeve is provided with an assembly port communicating with the chamber, and a diameter of an aperture of the assembly port is relatively smaller than an inner diameter of the chamber. The top board is mounted in the chamber of the elastic rubber sleeve to shield the assembly port of the elastic rubber sleeve, an outer diameter of the top board is relatively greater than the diameter of the aperture of the assembly port, and at least one screw hole and at least one vent are provided on the top board. The at least one first elastic pad is disposed in the chamber of the elastic rubber sleeve. The compression spring is disposed between the at least one first elastic pad and the top board.

The disclosed damper of the invention provides the more reliable action stroke mainly in conjunction with the provision of the compression spring to completely absorb the external impact or vibration energy. More particularly, when the external impact or vibration force disappears, the energy stored by the compression spring may quickly recover the elastic rubber sleeve to effectively enhance a vibration absorption effect and a response speed of the overall damper.

Furthermore, the damper includes a second elastic pad disposed between the compression spring and the top board.

Furthermore, the damper includes two metal washers respectively mounted on two ends of the compression spring.

Furthermore, the damper includes a second elastic pad disposed between the compression spring and the top board; and two metal washers respectively mounted on two ends of the compression spring.

Furthermore, the damper includes a second elastic pad disposed between the compression spring and the top board; and two metal washers respectively mounted on two ends of the compression spring; wherein the second elastic pad and one of the metal washers fixedly combined with the second elastic pad are respectively formed with two vents.

The elastic rubber sleeve is annually provided with at least one turn of arced section.

The first elastic pad and the second elastic pad are respectively fixedly combined with the metal washers mounted on the two ends of the compression spring.

The elastic rubber sleeve is annually provided with at least one turn of arced section; and the first elastic pad and the second elastic pad are respectively fixedly combined with the metal washers mounted on the two ends of the compression spring.

### BRIEF DESCRIPTION OF THE DRAWINGS

FIG. 1 is a schematic structure view showing a conventional overhead hoist transport (OHT).

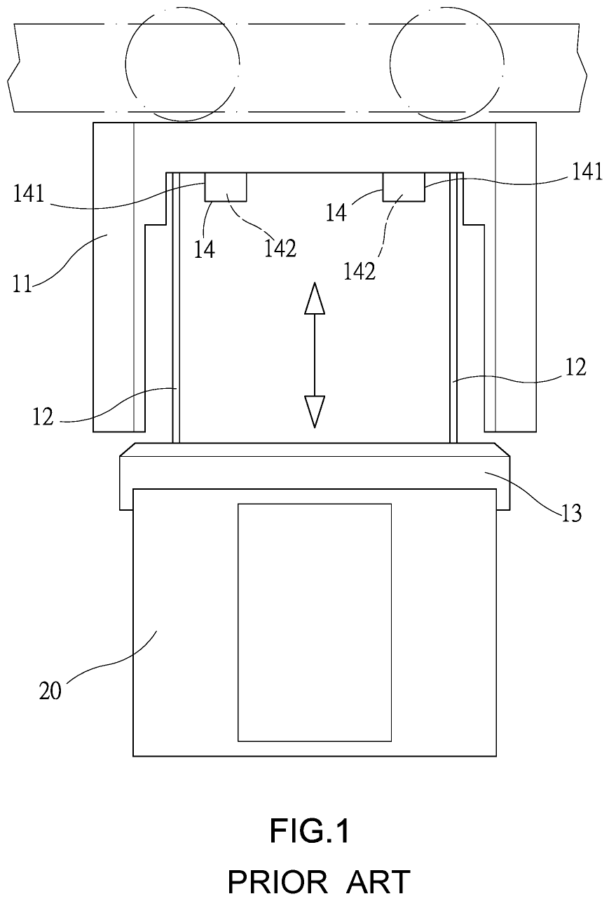

FIG. 2 is a pictorial view showing an outlook of a damper of the invention.

FIG. 3 is an exploded view showing a damper structure of a first embodiment of the invention.

FIG. 4 is a cross-sectional view showing the damper structure of the first embodiment of the invention.

FIG. 5 is a schematic operation view showing the damper of the invention.

FIG. 6 is an exploded view showing a damper structure of a second embodiment of the invention.

FIG. 7 is an exploded view showing a damper structure of a third embodiment of the invention.

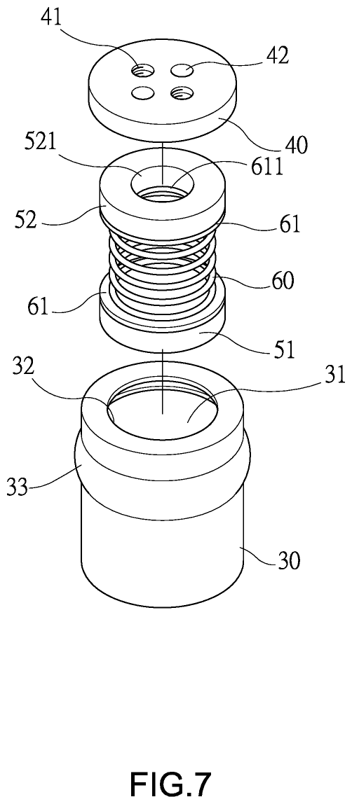

### DETAILED DESCRIPTION OF THE PREFERRED EMBODIMENTS

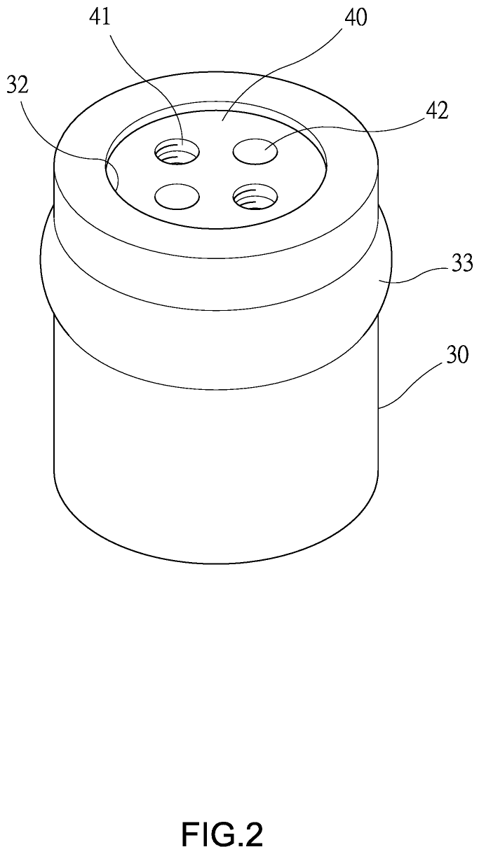

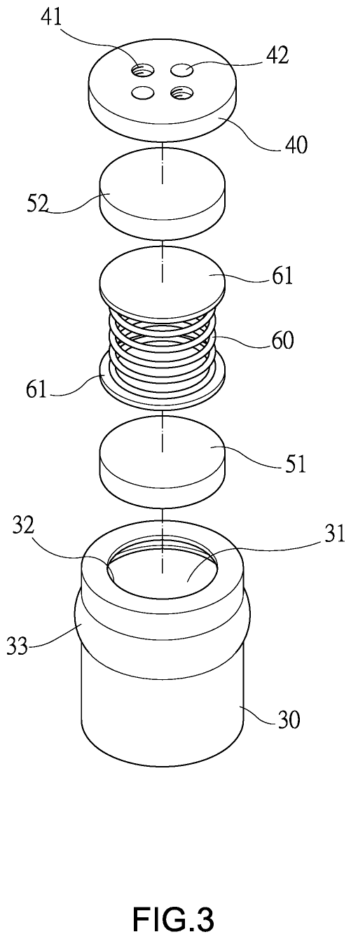

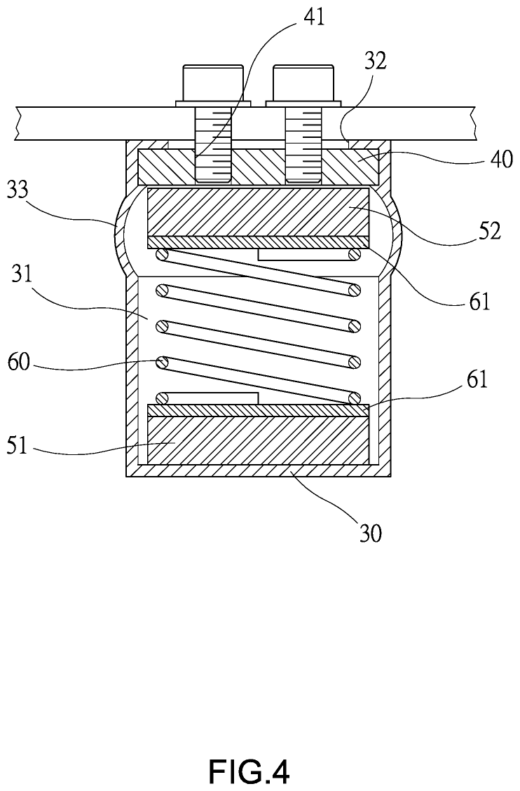

The invention mainly provides a damper capable of providing better vibration absorption effects, and thus enhancing the object delivery success rate. Referring to FIGS. 2 to 4, the damper of the invention basically includes an elastic rubber sleeve 30, a top board 40, at least one first elastic pad 51 and a compression spring 60.

The elastic rubber sleeve 30 has a substantially straight cylindrical chamber 31 formed inside the elastic rubber sleeve 30. A top portion of the elastic rubber sleeve 30 is provided with an assembly port 32 communicating with the chamber 31. A diameter of an aperture of the assembly port 32 is relatively smaller than an inner diameter of the chamber 31. Upon implementation, the elastic rubber sleeve 30 may be molded by plastic, silicone, rubber or other polymeric materials.

The top board 40 is mounted in the chamber 31 of the elastic rubber sleeve 30 to shield the assembly port 32 of the elastic rubber sleeve 30, an outer diameter of the top board 40 is relatively greater than a diameter of an aperture of the assembly port 32, and at least one screw hole 41 and at least one vent 42 are provided on the top board 40. Upon implementation, the top board 40 may be formed by way of metal cutting.

The at least one first elastic pad 51 is disposed in the chamber 31 of the elastic rubber sleeve 30; and the compression spring 60 is disposed between the at least one first elastic pad 51 and the top board 40. Upon implementation, the first elastic pad 51 may be molded by plastic, silicone, rubber or other polymeric materials.

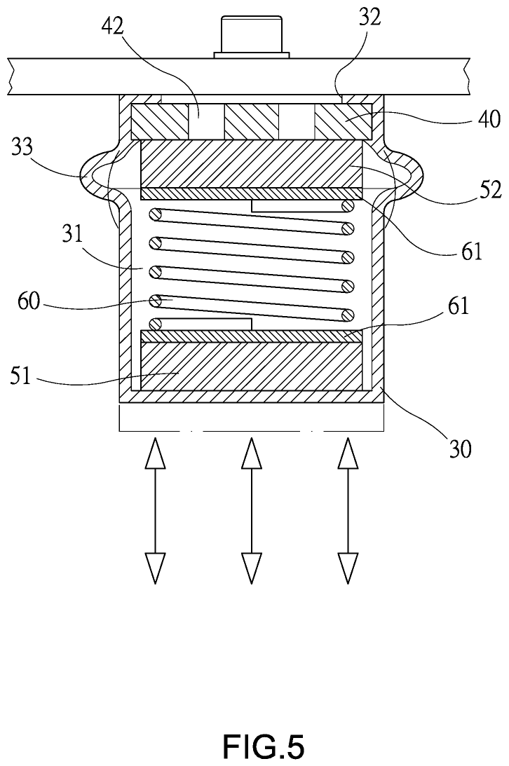

Referring also to FIG. 5, when the damper of the invention is used, the overall damper is mounted on a main body of a structure of an applied apparatus through the screw hole 41 of the top board 40. In addition to buffering the impact or vibration coming from the portion under the elastic rubber sleeve 30 using the elastic rubber sleeve 30 and the first elastic pad 51, the more reliable action stroke can further be provided in conjunction with the provision of the compression spring 60 so as to completely absorb the external impact or vibration energy. More particularly, when the external impact or vibration force disappears, the energy stored by the compression spring 60 can quickly recover the elastic rubber sleeve 30, and effectively enhance a vibration absorption effect and a response speed of the overall damper.

Therefore, the invention is particularly suitable to the application to the overhead hoist transport (OHT) for transporting or handling the wafer to effectively absorb the gravity-force (G-Force), which is generated when the wafer storage box impacts or vibrates or when the OHT speeds up, stops or turns. Thus, it is possible to prevent the wafer from being ruptured by collision, or to prevent the dust or particles for contaminating the wafer from being generated by the friction between the wafer and the wafer storage box. The output value and the production capacity of the wafer can be ensured with a relatively positive and reliable means.

Upon implementation of the damper of the invention, the overall damper may further include a second elastic pad 52 disposed between the compression spring 60 and the top board 40 to increase the damping effect. Alternatively, two metal washers 61 are further respectively mounted on two ends of the compression spring 60 to decrease the wear of other elements caused by the compression spring 60 and increase the recover smoothness of the compression spring 60 under the lining of the metal washer 61.

Of course, upon implementation of the damper of the invention, it is preferred that a second elastic pad 52 is further disposed between the compression spring 60 and the top board 40, and two metal washers 61 are respectively mounted on two ends of the compression spring 60.

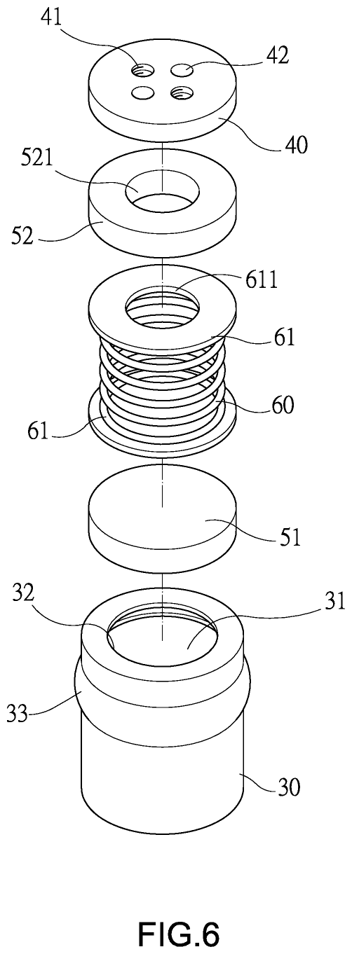

In the aspect of the damper of the invention when a second elastic pad 52 is disposed between the compression spring 60 and the top board 40, and two metal washers 61 are respectively mounted on two ends of the compression spring 60, the second elastic pad 52 and the metal washer 61 fixedly combined with the second elastic pad 52 may be respectively formed with a vent 521 and a vent 611, as shown in FIG. 6, to enhance the operation effect of the overall damper.

It is worth mentioning that in various aspects of the damper of the invention, the elastic rubber sleeve 30 may be annually provided with at least one turn of arced section 33. When the elastic rubber sleeve 30 is squeezed, the arced section 33 may be used as a deformation and compression region of the elastic rubber sleeve 30 corresponding to the squeezing force, so that the operation of the elastic rubber sleeve 30 becomes stabler and more reliable.

Furthermore, in the aspect of the damper of the invention when a second elastic pad 52 is disposed between the compression spring 60 and the top board 40, and two metal washers 61 are respectively mounted on two ends of the compression spring 60, the first elastic pad 51 and the second elastic pad 52 may be respectively fixedly combined with the metal washers 61 mounted on the two ends of the compression spring 60, so that the operation of the overall damper becomes stabler and more reliable.

In the aspect of the damper of the invention when a second elastic pad 52 is disposed between the compression spring 60 and the top board 40, and two metal washers 61 are respectively mounted on two ends of the compression spring 60, it is preferred to provide the structure pattern, in which the elastic rubber sleeve 30 is annually provided with at least one turn of arced section 33, and the first elastic pad 51 and the second elastic pad 52 are respectively fixedly combined with the metal washers 61 mounted on the two ends of the compression spring 60.

Specifically, the disclosed damper of the invention provides the more reliable action stroke mainly in conjunction with the provision of the compression spring. When the external impact or vibration force disappears, the energy stored by the compression spring rapidly recovers the elastic rubber sleeve to effectively enhance a vibration absorption effect and a response speed of the overall damper. The invention is particularly suitable to the application to the OHT for transporting or handling the wafer to effectively absorb the gravity-force (G-Force), which is generated when the wafer storage box impacts or vibrates or when the OHT speeds up, stops or turns. Thus, it is possible to prevent the wafer from being ruptured by collision, or to prevent the dust or particles for contaminating the wafer from being generated by the friction between the wafer and the wafer storage box. The output value and the production capacity of the wafer can be ensured with a relatively positive and reliable means.

Technical contents and technical characteristics of the invention have been set forth in the foregoing description. However, those skilled in the art may still make various substitutions and modifications without departing from the spirit of the present invention based on the disclosure of the invention. Therefore, the scope of claims of the invention is not limited to the disclosed embodiments, but includes various alternatives and modifications, which do not depart from the invention and are covered by the appended claims.

What is claimed is:

1. A damper, comprising an elastic rubber sleeve, a top board, at least one first elastic pad and a compression spring, wherein:
the elastic rubber sleeve has a substantially straight cylindrical chamber formed inside the elastic rubber sleeve, a top portion of the elastic rubber sleeve is provided with an assembly port communicating with the chamber, and a diameter of an aperture of the assembly port is relatively smaller than an inner diameter of the chamber;
the top board is mounted in the chamber of the elastic rubber sleeve to shield the assembly port of the elastic rubber sleeve, an outer diameter of the top board is relatively greater than the diameter of the aperture of the assembly port, and at least one screw hole and at least one vent are provided on the top board;
the at least one first elastic pad is disposed in the chamber of the elastic rubber sleeve; and
the compression spring is disposed between the at least one first elastic pad and the top board.

2. The damper according to claim 1, further comprising a second elastic pad disposed between the compression spring and the top board.

3. The damper according to claim 1, further comprising two metal washers respectively mounted on two ends of the compression spring.

4. The damper according to claim 1, further comprising: a second elastic pad disposed between the compression spring and the top board; and two metal washers respectively mounted on two ends of the compression spring.

5. The damper according to claim 1, further comprising: a second elastic pad disposed between the compression spring and the top board; and two metal washers respectively mounted on two ends of the compression spring, wherein the second elastic pad and one of the metal washers fixedly combined with the second elastic pad are respectively formed with two vents.

6. The damper according to claim 5, wherein the elastic rubber sleeve is annually provided with at least one turn of arced section.

7. The damper according to claim 5, wherein the first elastic pad and the second elastic pad are respectively fixedly combined with the metal washers mounted on the two ends of the compression spring.

8. The damper according to claim 4, wherein the elastic rubber sleeve is annually provided with at least one turn of arced section; and the first elastic pad and the second elastic pad are respectively fixedly combined with the metal washers mounted on the two ends of the compression spring.

9. The damper according to claim 5, wherein the elastic rubber sleeve is annually provided with at least one turn of arced section; and the first elastic pad and the second elastic pad are respectively fixedly combined with the metal washers mounted on the two ends of the compression spring.
